(19) United States
(12) Patent Application Publication
(10) Pub. No.: US 2012/0217541 A1
(43) Pub. Date: Aug. 30, 2012

(54) IGBT WITH INTEGRATED MOSFET AND FAST SWITCHING DIODE

(75) Inventor: Fu-Yuan HSIEH, Banciao City (TW)

(73) Assignee: FORCE MOS TECHNOLOGY CO., LTD., Banciao City (TW)

(21) Appl. No.: 13/033,627

(22) Filed: Feb. 24, 2011

(51) Int. Cl. H01L 23/58; H01L 29/74

(52) U.S. Cl. 257/140; 257/E23.002; 257/E29.211

(57) ABSTRACT

A power semiconductor device comprising a trench IGBT, a trench MOSFET and a fast switching diode for reduction of turn-on loss is disclosed. The inventive semiconductor power device employs a fast switching diode instead of body diode in the prior art. Furthermore, the inventive semiconductor power device further comprises an additional ESD protection diode between emitter metal and gate metal.

### FIELD OF THE INVENTION

This invention relates generally to the device configuration for fabricating the semiconductor power device. More particularly, this invention relates to an improved and novel device configuration for providing a power semiconductor power device comprising a trench IGBT (Insulation Gate Bipolar Transistor), trench MOSFET (Metal Oxide Semiconductor Field Effect Transistor) and fast switching diode for reduction of turn-on loss.

### BACKGROUND OF THE INVENTION

FIG. 1A shows an equivalent circuit of a hybrid trench IGBT and trench MOSFET with a parasitic body diode for on-resistance reduction at Vice (Voltage between collector and emitter, similarly hereinafter) below 0.6V, please refer to the cross sectional view in FIG. 1B having a parasitic P+ body diode underneath each the trenched source-body contact which is disclosed in U.S. Pat No. 6,627,961.

However, the P+ heavily doped parasitic body diode in the trench MOSFET has low switching speed and high reverse recovery current due to the fact that high values of Trr (body diode reverse recovery time, similarly hereinafter) and Qrr (body diode reverse recovery charge, similarly hereinafter) increase complimentary MOSFET turn-on loss. Moreover, kr (body diode reverse recovery current, similarly hereinafter) may increase to a point at which the circuit is damaged.

Please refer to FIG. 1C for wave form of body diode reverse recovery current. The prior art discussed above inherently has wave form 21 (solid line) of body diode showing a high peak reverse recovery current Irrp1 with a steep slope of dIrr1/dt and ringing because the p+ heavily doped parasitic body diode in FIG. 1B is heavily doped that causes high hole injection efficiency. The softness of the recovery wave form corresponds to the slope of Irr1 (i.e. dIrr1/dt) as it tends toward zero after time t. The stepper the slope, the less soft the recovery wave form and the greater the chance that the ringing will result. The ringing is caused by the kr overshoots too quickly and then oscillates back and forth till zero, and Qrr has high value as mentioned above as defined by 0.5*Irrp*trr. The softness is mainly determined by P− type doping concentration of the P+ body diode. The higher doping concentration, the less softness. The wave form 22 (dash line) of body diode having less P-type doping concentration shows a less peak reverse recovery current Irrp2 with a less slope of dIrr2/dt and no ring oscillation.

Accordingly, it would be desirable to provide a new and improved semiconductor power device configuration to avoid the constraint discussed above.

### SUMMARY OF THE INVENTION

It is therefore an aspect of the present invention to provide a new and improved semiconductor power device comprising a trench IGBT, trench MOSFET and fast switching diode for reduction of switching loss, further comprising: an emitter node of the trench IGBT connected to a source node of the trench MOSFET and an anode node of the fast switching diode; a collector node of the trench IGBT connected to a drain node of the trench MOSFET and a cathode node of the fast switching diode; and a gate node of the trench IGBT connected to that of the trench MOSFET.

In accordance with another aspect of the present invention, the novel semiconductor power device can be implemented by a trench MOSFET monolithically integrated with a fast switching diode, copacked together with a trench IGBT of a separate discrete die on a common heat sink in same package; or a trench IGBT monolithically integrated with a trench MOSFET and a fast switching diode into a same die.

In accordance with another aspect of the present invention, the fast switching diode can be implemented by a Schottky diode with Schottky barrier layer or a soft recovery diode formed by PN junction.

In accordance with another aspect of the present invention, the trench IGBT can by implemented by a trench PT (Punch-Through) IGBT or a trench NPT (Non-Punch-Through) IGBT.

In accordance with another aspect of the present invention, the inventive semiconductor power device further comprises an ESD gate protection diode.

Briefly, in a preferred embodiment of the present invention, the inventive semiconductor power device comprises a copacked trench PT IGBT with a trench MOSFET monolithically integrated with a Schottky diode. The trench PT IGBT is formed in an N− epitaxial layer onto an N+ epitaxial layer supported onto a P+ substrate coated with collector metal on rear side. The trench PT IGBT further comprises: a plurality of trenched gates which are spaced apart by a plurality of P base regions and a plurality of n+ emitter regions encompassed in the P base regions; a plurality of trenched emitter-base contacts penetrating through an insulation layer and the n+ emitter regions, and extending into the P base regions between every two adjacent of the trenched gates; a plurality of p+ base ohmic contact doped regions formed within the P base regions and surrounding at least bottom of each the trenched emitter-base contact underneath the n+ emitter region; an emitter metal overlying the insulation layer and connected to all the trenched emitter-base contacts. The trench MOSFET monolithically integrated with a Schottky diode is formed in the N− epitaxial layer supported on an N+ substrate coated with drain metal on rear side. The trench MOSFET monolithically integrated with a Schottky diode further comprises: a plurality of the trenched gates formed in the second N− epitaxial layer; a plurality of P body regions encompassing a plurality of n+ source regions between every two adjacent of the trenched gates in the trench MOSFET portion; a plurality of trenched source-body contacts penetrating through the insulation layer in the trench MOSFET portion and the n+ source regions, and extending into the P body regions in the trench MOSFET portion; a plurality of p+ body ohmic contact doped regions formed within the P body regions and surrounding at least bottom of each the trenched source-body contact underneath the n+ source regions in the trench MOSFET portion; a plurality of trenched anode contacts penetrating through the insulation layer and extending into the second N− epitaxial layer in the Schottky diode portion; a plurality of n− Schottky barrier height enhancement regions surrounding bottom and sidewall of each the trenched anode contact within the second N− epitaxial layer in the Schottky diode portion.

Briefly, in a second preferred embodiment of the present invention, the inventive semiconductor power device has a similar configuration with the first embodiment, except that the trench MOSFET is monolithically integrated with a soft recovery diode which is formed by a PN junction. Therefore, in the soft recovery diode portion, bottom and sidewall of each the trenched anode contact is surrounded by a p type anode doped region P* having peak concentration less than 1E19 cm⁻³ instead of the n− Schottky barrier height enhancement region within the second N− epitaxial layer.

Briefly, in a third preferred embodiment of the present invention, the inventive semiconductor power device has a similar configuration with the first embodiment, except that the trench IGBT is a trench NPT IGBT which is formed in an N− FZ (Float Zone) of which rear side has P+ doped region as collector region of the trench NPT IGBT.

Briefly, in a fourth preferred embodiment of the present invention, the inventive semiconductor power device has a similar configuration with the second embodiment, except that the trench IGBT is a trench NPT IGBT which is formed in an N− FZ of which rear side has P+ doped region as collector region of the trench NPT IGBT.

Briefly, in a fifth preferred embodiment of the present invention, the inventive semiconductor power device comprises a trench NPT IGBT monolithically integrated with a trench MOSFET and a Schottky diode into a same die. The trench NPT IGBT, the trench MOSFET and the Schottky diode are all formed in an N− FZ of which rear side has P+ doped region as collector region of the trench NPT IGBT in the trench NPT IGBT portion, and has an N+ doped region as drain region of the trench MOSFET and as cathode region of the Schottky diode in the trench MOSFET and the Schottky diode portions, respectively. The N+ doped region is also disposed in a termination region. The fifth embodiment of the present invention further comprises: a plurality of trenched gates formed in the N− FZ substrate; a plurality of P base regions locating between every two adjacent of the trenched gates in the trench NPT IGBT and the trench MOSFET portions; a plurality of n+ emitter regions encompassed in and near top surface of the P base regions; a plurality of trenched emitter-base contacts penetrating through an insulation layer and the n+ emitter regions, and extending into the P base regions in the trench NPT IGBT and the trench MOSFET portions; a plurality of p+ base ohmic contact doped regions within the P base regions and surrounding at least bottom of each the trenched emitter-base contact underneath the n+ emitter region; a plurality of P body regions encompassing a plurality of n+ source regions between every two adjacent of the trenched gates in the trench MOSFET portion; a plurality of trenched source-body contacts penetrating through the insulation layer and the n+ source regions, and extending into the P body regions in the trench MOSFET portion; a plurality of p+ body ohmic contact doped regions formed within the P body regions and surrounding at least bottom of each the trenched source-body contact underneath the n+ source regions in the trench MOSFET portion; a plurality of trenched anode contacts penetrating through the insulation layer and extending into the N− FZ substrate in the Schottky diode portion; a plurality of n− Schottky barrier height enhancement regions surrounding bottom and sidewall of each the trenched anode contact within the N− FZ substrate in the Schottky diode portion; an emitter metal overlying the insulation layer and connected to the trenched emitter-base contacts, trenched source-body contacts and trenched anode contacts; a collector metal disposed on rear side of the P+ and the N+ doped regions.

Briefly, in a sixth preferred embodiment of the present invention, the inventive semiconductor power device has a similar configuration with the fifth embodiment, except that the trench MOSFET is monolithically integrated with a soft recovery diode. Therefore, in the soft recovery diode portion, bottom and sidewall of each the trenched anode contact is surrounded by a P* anode doped region instead of the n− Schottky barrier height enhancement region within the N− FZ substrate to form a P*/N epitaxial junction diode.

Briefly, in a seventh embodiment of the present invention, the inventive semiconductor power device has a similar configuration with the fifth embodiment, except further comprising an ESD gate protection diode next to the Schottky diode portion. The ESD gate protection diode includes an array of doped regions alternatively doped with n+ type dopant and p type dopant with a first and last doped regions doped with n+ type dopant wherein one of the two doped regions is connected to the emitter metal and another connected to gate metal by trenched ESD contact. Specially, underneath each of the trenched ESD contact, a trenched gate is formed as a buffer layer to avoid ESD diode shortage issue to the base or body regions disposed underneath the ESD gate protection diode in case the trenched ESD contact is overetched through the n+ doped regions.

Briefly, in an eighth embodiment of the present invention, the inventive semiconductor power device has a similar configuration with the sixth embodiment, except further comprising an ESD gate protection diode next to the soft recovery diode. The ESD gate protection diode includes an array of doped regions alternatively doped with n+ type dopant and p type dopant with a first and last doped regions doped with n+ type dopant wherein one of the two doped regions connected to the emitter metal and another connected to gate metal by trenched ESD contact. Specially, underneath each of the trenched ESD contact, a trenched gate is formed as a buffer layer to avoid the ESD shortage issue.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is an equivalent circuit of a hybrid IGBT and MOSFET with a parasitic body diode of prior art.

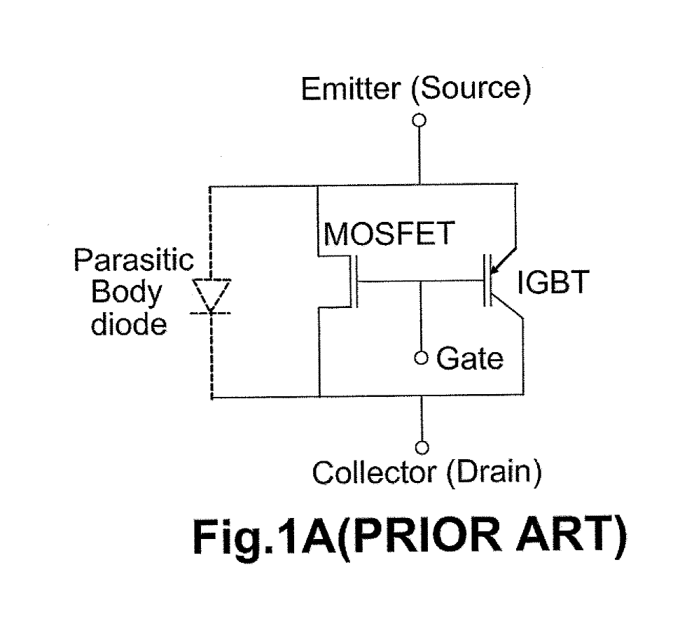

FIG. 1B is a cross-section view of an IGBT monolithically integrated with MOSFET having a parasitic body diode of prior art.

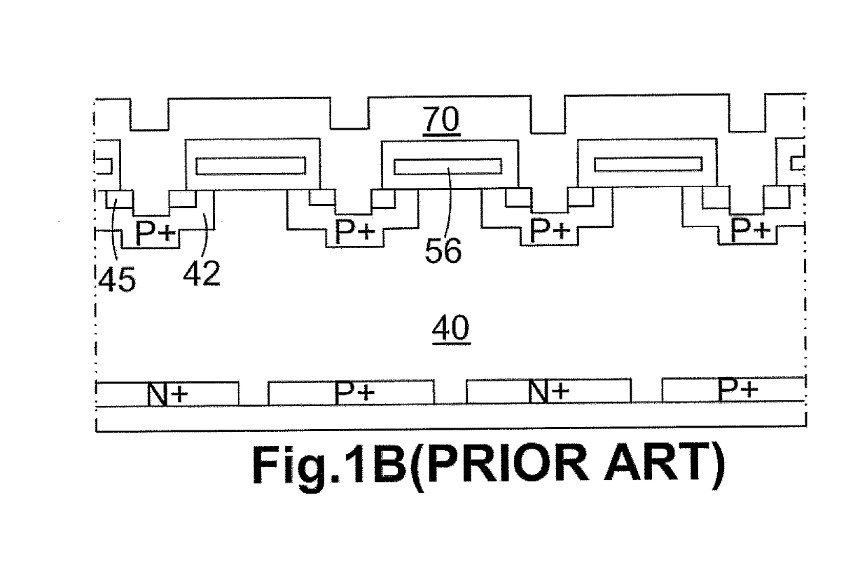

FIG. 1C is a wave form showing body diode reverse recovery current.

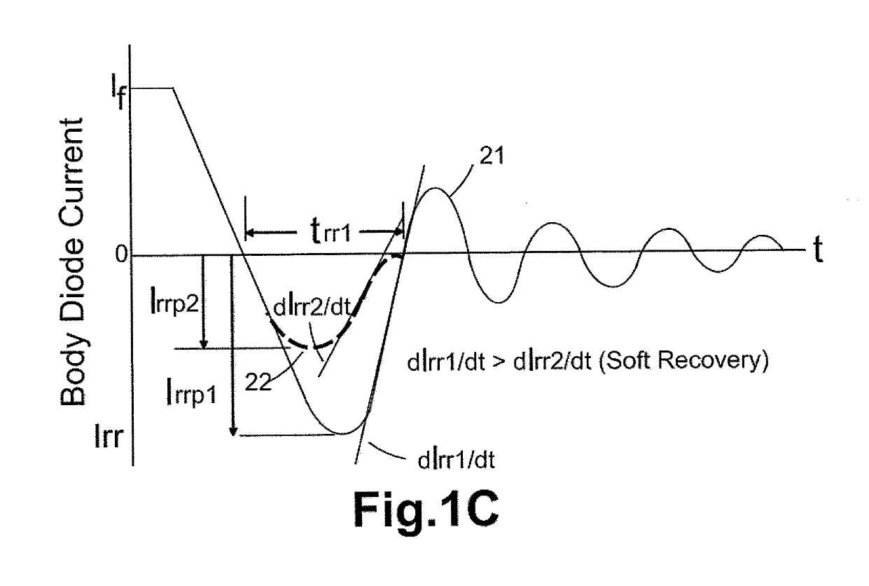

FIG. 2 is another equivalent circuit of copacked trench IGBT with a trench MOSFET monolithically integrated with a Schottky diode according to the present invention.

FIG. 3 is another equivalent circuit of copacked trench IGBT with a trench MOSFET monolithically integrated with a soft recovery diode according to the present invention.

FIG. 4 is another equivalent circuit of monolithically integrated trench IGBT with a trench MOSFET and a Schottky diode as well as an ESD gate protection diode according to the present invention.

FIG. 5 is another equivalent circuit of monolithically integrated trench IGBT with a trench MOSFET, a soft recovery diode as well as an ESD gate protection diode according to the present invention.

FIG. 6A is a cross-sectional view of the PT trench IGBT portion according to the first and second embodiments.

FIG. 6B is a cross-sectional view of a copacked NPT trench IGBT according to the third and fourth embodiments.

FIG. 6C is a cross-sectional view of the trench MOSFET monolithically integrated with the Schottky diode portion according to the first and third embodiments.

FIG. 6D is a cross-sectional view of the trench MOSFET monolithically integrated with the soft recovery diode portion according to the second and fourth embodiments.

FIG. 7A is a cross-sectional view of the present invention according to the fifth embodiment.

FIG. 7B is a cross-sectional view of the present invention according to the sixth embodiment.

FIG. 8A is a cross-sectional view of the present invention according to the seventh embodiment.

FIG. 8B is a cross-sectional view of the present invention according to the eighth embodiment.

### DETAILED DESCRIPTION OF THE EMBODIMENTS

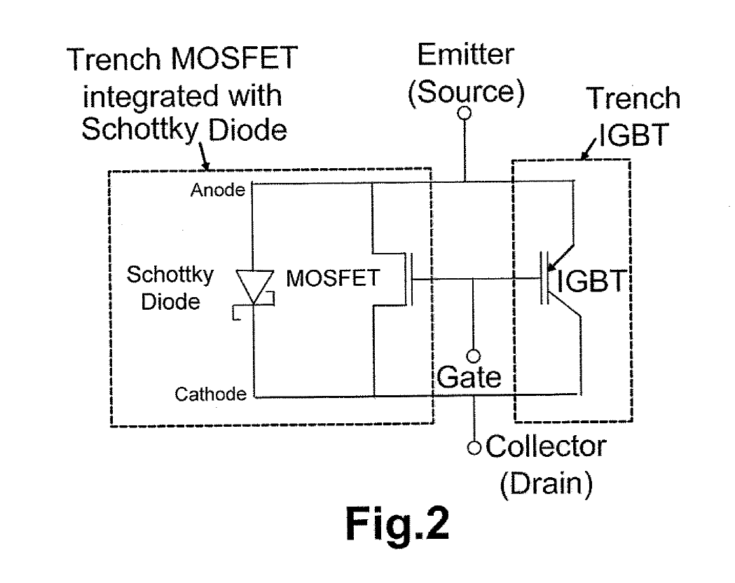

Please refer to FIG. 2 for an equivalent circuit of the present invention comprising a copacked trench IGBT with a trench MOSFET monolithically integrated with a Schottky diode in a same package, wherein the trench IGBT can be implemented by a trench PT IGBT or by a trench NPT IGBT. The equivalent circuit comprises an emitter node of the trench IGBT connected to a source node of the trench MOSFET and an anode node of the Schottky diode, a collector node of the trench IGBT connected to a drain node of the trench MOSFET and cathode node of the Schottky diode, and a gate node of the trench IGBT connected to that of the trench MOSFET.

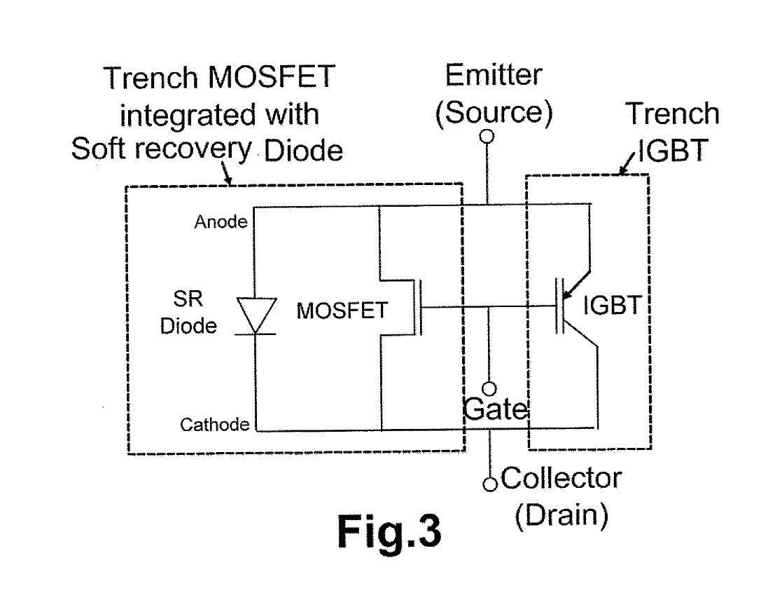

Please refer to FIG. 3 for an equivalent circuit of the present invention comprising a copacked trench IGBT with a trench MOSFET monolithically integrated with a soft recovery diode in a same package, wherein the trench IGBT can be implemented by a trench PT IGBT or by a trench NPT IGBT.

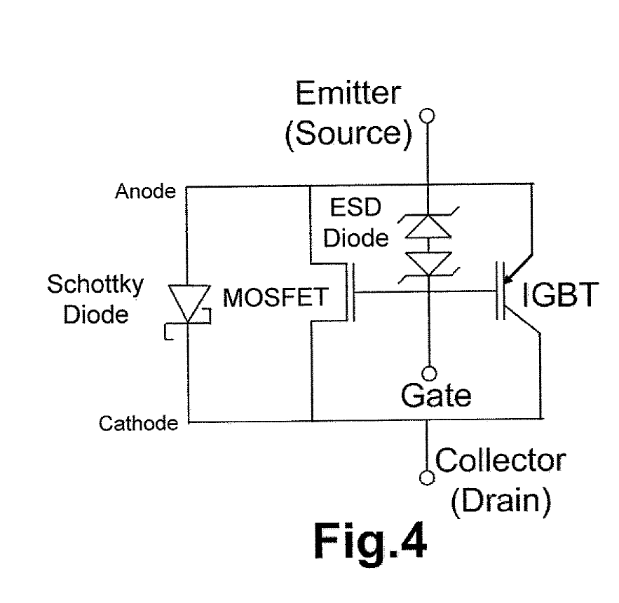

Please refer to FIG. 4 for an equivalent circuit of the present invention comprising an integrated trench IGBT with a trench MOSFET and a Schottky diode on a single die. More particularly, an ESD gate protection diode is optionally added between the emitter region and gate region.

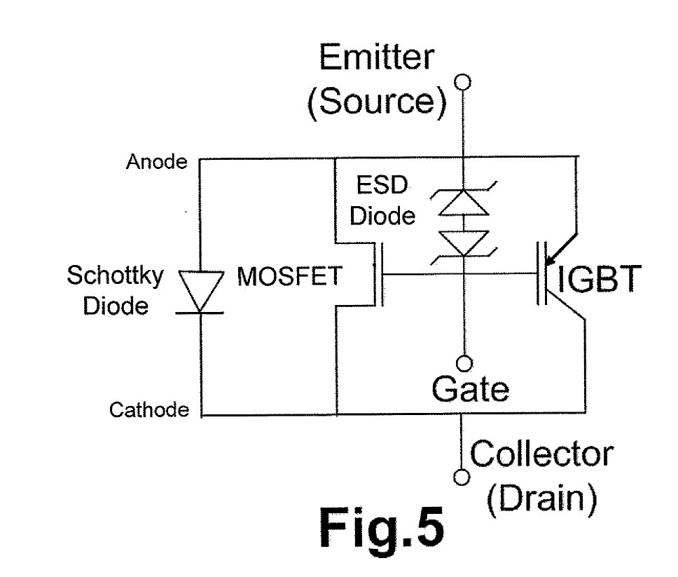

Please refer to FIG. 5 for an equivalent circuit of the present invention comprising an integrated trench IGBT with a trench MOSFET and a soft recovery diode on a single die. More particularly, an ESD gate protection diode is optionally added between the emitter region and gate region.

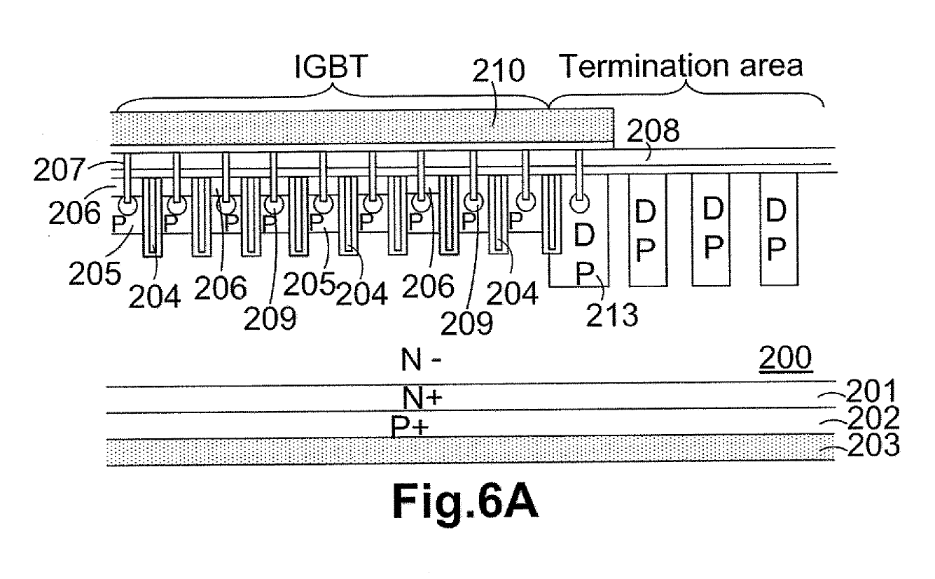

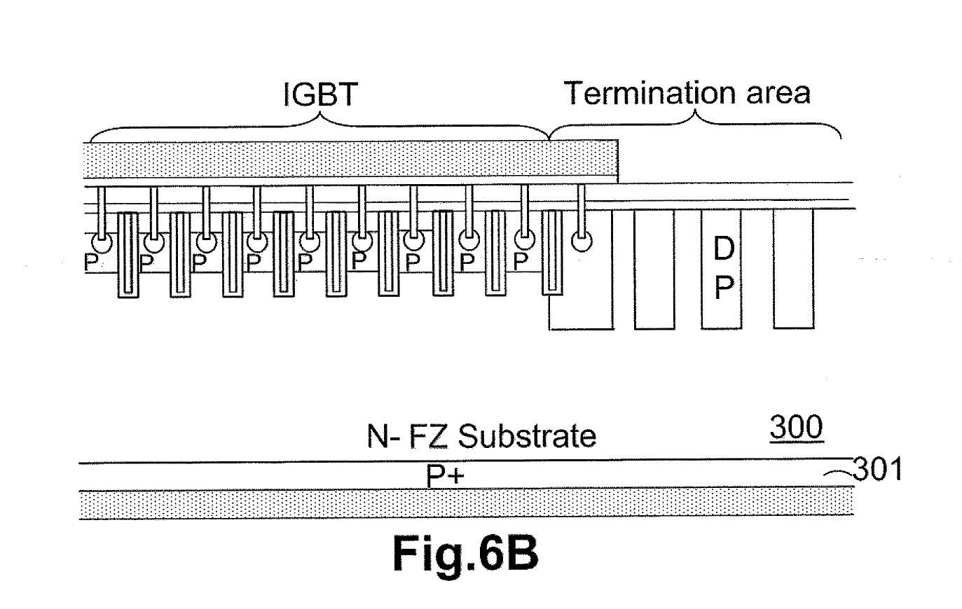

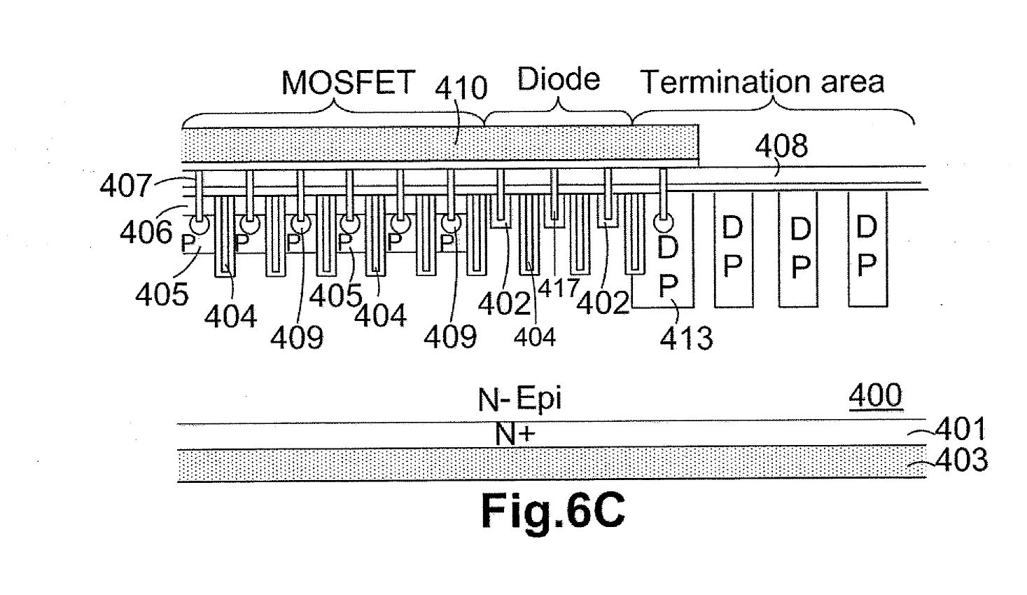

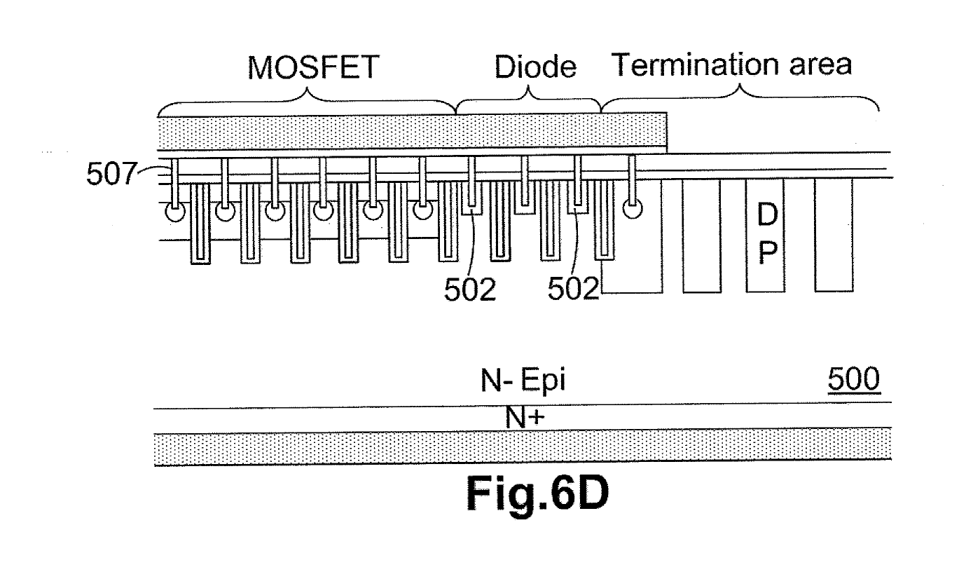

Please refer to FIG. 6A for cross-sectional view of a copacked trench PT IGBT portion which formed in an N− epitaxial layer 200 grown onto an N+ epitaxial layer 201 supported onto a P+ substrate 202 coated with collector metal 203 on rear side. A plurality of trenched gates 204 are formed in the first N− epitaxial layer 200 and surrounded by a plurality of P base regions 205 encompassing n+ emitter regions 206 near top surface. A plurality of trenched emitter-base contacts 207 are penetrating through an insulation layer 208, the n+ emitter regions 206 and extending into the P base regions 205. A plurality of p+ base ohmic contact doped regions 209 are formed within the P base regions 205 and surrounding at least bottom of each the trenched emitter-base contacts 207. An emitter metal 210 is formed overlying the insulation layer 208 and connected to all the trenched emitter-base contacts 207 to contact with the P base regions 205, the n+ emitter regions 206, as well as a deep P well 213 in termination area which comprising multiple of the deep P wells.

Please refer to FIG. 6B for cross-sectional view of a copacked trench NPT IGBT portion which has similar configuration with FIG. 6A, except that the trench NPT IGBT is formed in an N− FZ substrate 300 of which rear side has a P+ doped region 301 as collector region.

Please refer to FIG. 6C for cross-sectional view of a trench MOSFET monolithically integrated with a Schottky diode which formed in an N− epitaxial layer 400 grown on an N+ epitaxial layer 401 coated with drain metal 403 on rear side. A plurality of trenched gates 404 are formed in the N− epitaxial layer 400 and surrounded by a plurality of P body regions 405 encompassing n+ source regions 406 near top surface in the trenched MOSFET portion. A plurality of trenched source-body contacts 407 are penetrating through an insulation layer 408, the n+ source regions 406 and extending into the P body regions 405 in the trench MOSFET portion. A plurality of p+ body ohmic contact doped regions 409 are formed within the P body regions 406 and surrounding at least bottom of each the trenched source-body contact 407 underneath the n+ source regions 406 in the trenched MOSFET portion. A plurality of trenched anode contacts 417 are penetrating through an insulation layer 408 and extending into the N− epitaxial layer 400 wherein the source and body regions in the trench MOSFET portion do not exist in the Schottky diode portion. A plurality of n− Schottky barrier height enhancement regions 402 in contact with a silicide layer are formed surrounding bottom and sidewall of each the trenched anode contact 417 within the N− epitaxial layer 400 in the Schottky diode portion. A source metal 410 is formed overlying the insulation layer 408 and connected to the P body regions 405 and the n+ source regions 406 in the trenched MOSFET portion and the n− barrier height enhancement regions 402 in the Schottky diode portion through contact metal plugs filled in the trenched source-body contacts 407 and the trenched anode contacts 417. Meanwhile, the source metal 410 is connected to a deep P well 413 in termination area which comprising multiple of the deep P wells.

Please refer to FIG. 6D for a trench MOSFET monolithically integrated with a soft recovery diode which has similar configuration with FIG. 6C, except that in the soft recovery diode portion, bottom and sidewall of each the trenched source-body contact 517 is surrounded by a P* anode doped region 502 within the N− epitaxial layer 500, having peak concentration less than 1E19 cm⁻³.

Therefore, according to the present invention, the first preferred embodiment comprises copacked trench PT IGBT in FIG. 6A and trench MOSFET monolithically integrated with a Schottky diode in FIG. 6C; the second preferred embodiment comprises copacked trench NPT IGBT in FIG. 6B and trench MOSFET monolithically integrated with a Schottky diode in FIG. 6C; the third preferred embodiment comprises copacked trench PT IGBT in FIG. 6A and trench MOSFET monolithically integrated with a soft recovery diode in FIG. 6D; the fourth preferred embodiment comprises copacked trench NPT IGBT in FIG. 6B and trench MOSFET monolithically integrated with a soft recovery diode in FIG. 6D.

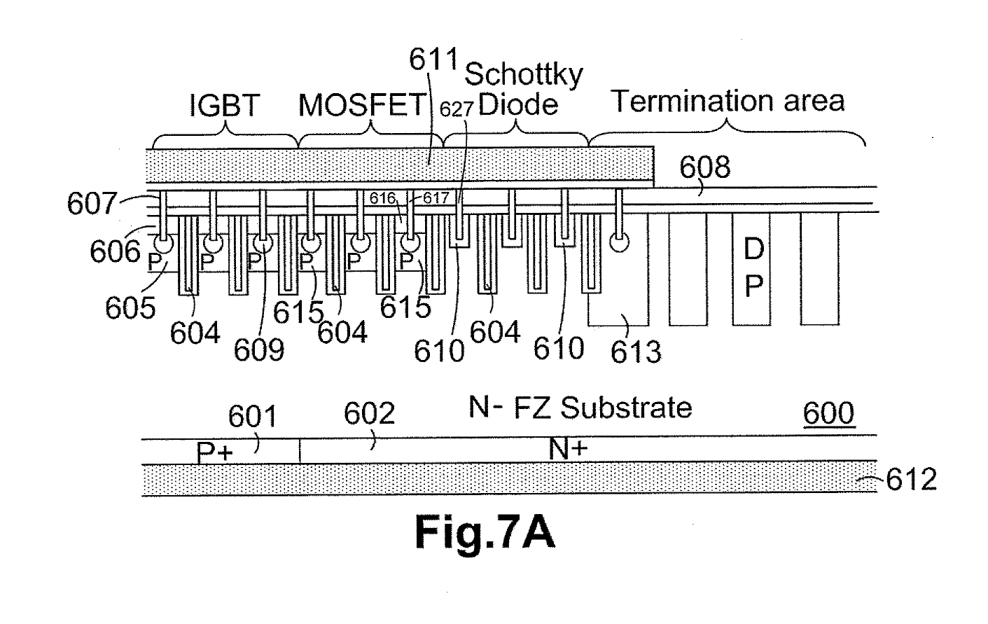

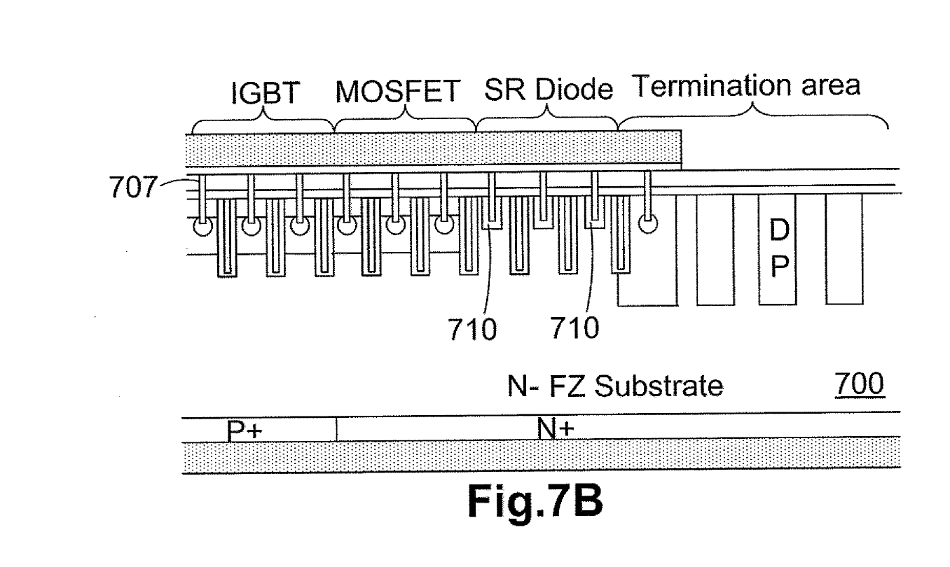

Please refer to FIG. 7A for cross-sectional view of the fifth preferred embodiment of the present invention which comprises a trench NPT IGBT monolithically integrated with a trench MOSFET and a Schottky diode into a same die. The fifth preferred embodiment is formed in an N− FZ substrate 600 of which rear side has a p+ doped region 601 as collector region in the trench NPT IGBT portion, and an N+ doped region 602 as drain region in the trench MOSFET and as cathode region in the Schottky diode portion. A plurality of trenched gates 604 are formed in the N− FZ substrate 600 and surrounded by a plurality of P base regions 605 encompassing n+ emitter regions 606 in the trench NPT IGBT portion and the trench MOSFET portion. A plurality of trenched emitter-base contacts 607 are penetrating through an insulation layer 608, the n+ emitter regions 606 and extending into the P base regions 605 in trench NPT IGBT portion. A plurality of p+ base ohmic contact doped regions 609 are formed within the P base regions 605 and surrounding at least bottom of each the trenched emitter-base contact 607. A plurality of trenched source-body contacts 617 are penetrating through the insulation layer 608, the n+ source regions 616 and extending into the P body regions 615 in trench MOSFET portion. A plurality of trenched anode contacts 627 are penetrating through the insulation layer 608 and extending into the N− FZ substrate in Schottky diode portion. A plurality of n− Schottky barrier height enhancement regions 610 in contact with a silicide layer are formed surrounding bottom and sidewall of each the trenched anode contact 627 within the N− FZ substrate 600 in the Schottky diode portion. An emitter metal 611 is formed overlying the insulation layer 608 and connected to the P base regions 605 and the n+ emitter regions 606 in the trench NPT IGBT portion, the body region 615 and n+ source region 616 in the trench MOSFET portion, and the anode region in the Schottky diode portion through contact metal plugs filled in the trenched emitter-base, source-body and anode contacts. Meanwhile, the emitter metal 611 is connected to a deep P well 613 in termination area which comprises multiple of the deep P wells. A collector metal 612 is formed on rear side of the P+ doped region 601 and the N+ doped region 602.

Please refer to FIG. 7B for cross-sectional view of the sixth preferred embodiment of the present invention which comprises a trench NPT IGBT monolithically integrated with a trench MOSFET and a soft recovery diode into a same die. Therefore, bottom and sidewall of each the trenched anode contact 717 is surrounded by a P* anode doped region 710 within the N− epitaxial layer 700.

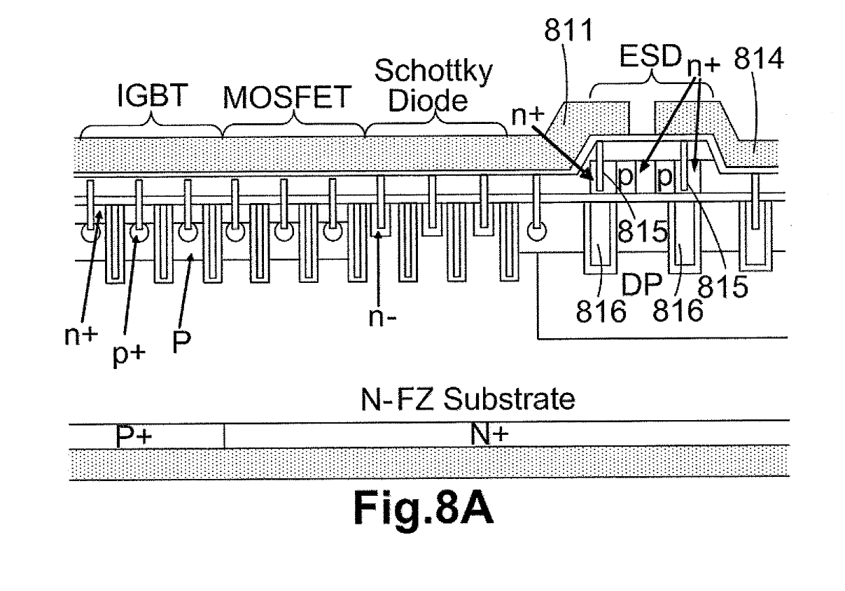

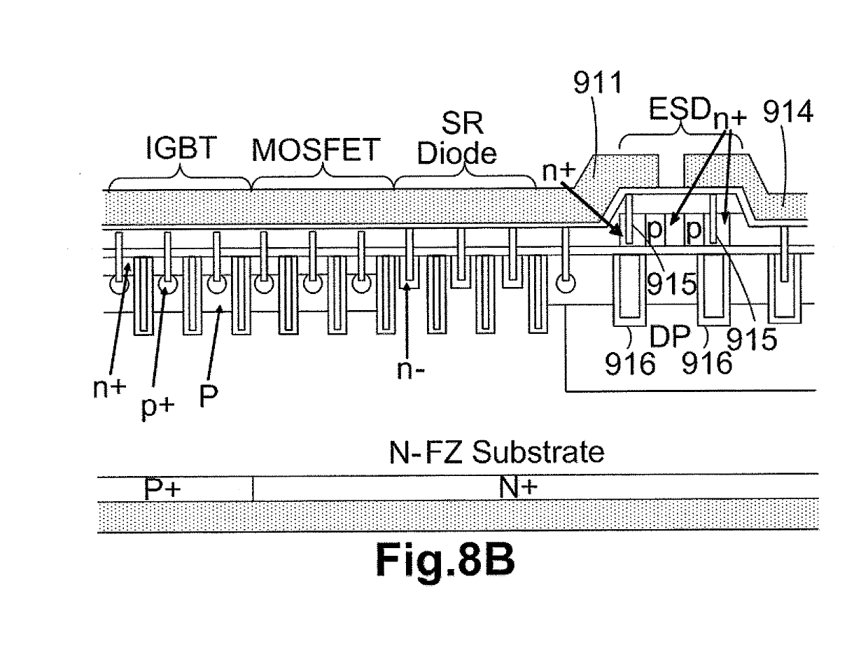

Please refer to FIG. 8A for cross-sectional view of the seventh preferred embodiment of the present invention with an additional ESD gate protection diode comparing to FIG. 7A. The ESD gate protection diode comprises an array of doped regions alternatively doped with n+ type dopant and p type dopant with a first and last doped regions with n+ type dopant wherein one of two doped regions connected to the emitter metal 811 and another connected to gate metal 814 by trenched ESD contacts 815. Specially, underneath each of the trenched ESD contact, a trenched gate 816 is formed as a buffer layer to avoid the ESD diode shortage issue to the base or body regions disposed underneath the ESD gate protection diode in case the trenched ESD contact is overetched through the n+ doped regions.

Please refer to FIG. 8B for cross-sectional view of the eighth preferred embodiment of the present invention with an additional ESD gate protection diode comparing to FIG. 7B. The ESD gate protection diode comprises an array of doped regions alternatively doped with n+ type dopant and p type dopant with a first and last doped regions with n+ type dopant wherein one of two doped regions connected to the emitter metal 911 and another connected to gate metal 914 by trenched ESD contacts 915. Specially, underneath each of the trenched ESD contact, a fourth-type trenched gate 916 is formed as a buffer layer to avoid the ESD diode shortage issue.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A power semiconductor device comprising a trench IGBT, a trench MOSFET and a fast switching diode for reduction of switching loss further comprising:
an emitter node of said trench IGBT connected to a source node of said trench MOSFET and an anode node of said fast switching diode;
a collector node of said trench IGBT connected to a drain node of said trench MOSFET and a cathode node of said fast switching diode; and
a gate node of said trench IGBT connected to that of said trench MOSFET.

2. The semiconductor power device of claim 1, wherein said trench MOSFET monolithically integrated with said fast switching diode, copacked together with said trench IGBT of a separate discrete die on a common heat sink in same package.

3. The semiconductor power device of claim 1, wherein said trench IGBT monolithically integrated with said trench MOSFET and said fast switching diode into a same die.

4. The semiconductor power device of claim 1, wherein said fast switching diode is a Schottky diode with Schottky barrier layer.

5. The semiconductor power device of claim 1, wherein said fast switching diode is a soft recovery diode formed with PN junction wherein said peak concentration of P region in PN junction is less than 1E19 cm⁻³.

6. The semiconductor power device of claim 2, wherein said trench IGBT is a trench PT IGBT.

7. The semiconductor power device of claim 2, wherein said trench IGBT is a trench NPT IGBT.

8. The semiconductor power device of claim 1 further comprising an ESD gate protection diode.

9. The semiconductor power device of claim 6 further comprising:
a plurality of trenched gates formed in an epitaxial layer lightly doped with a first conductivity type onto another epitaxial layer heavily doped with said first conductivity type grown on a substrate heavily doped with a second conductivity type;
a plurality of base regions doped with said second conductivity type extending between every two adjacent of said trenched gates;
a plurality of emitter regions heavily doped with said first conductivity type encompassed in said base regions;
a plurality of trenched emitter-base contacts penetrating through an insulation layer, said emitter regions and extending into said base regions;
a base ohmic contact doped region heavily doped with said second conductivity type within said base region surrounding at least bottom of each said trenched emitter-base contact underneath said emitter region;
an emitter metal onto said insulation layer and connected to all said trenched emitter-base contacts.

10. The semiconductor power device of claim 7 further comprising:
a plurality of trenched gates formed in a FZ substrate lightly doped with a first conductivity type;
a heavily doped region with a second conductivity type is formed on rear side of said FZ substrate as collector region;
a plurality of base regions doped with said second conductivity type extending between every two adjacent of said trenched gates;
a plurality of emitter regions heavily doped with said first conductivity type encompassed in said base regions;
a plurality of trenched emitter-base contacts penetrating through an insulation layer, said emitter regions and extending into said base regions;
a base ohmic contact doped region heavily doped with said second conductivity type within said base region surrounding at least bottom of each said trenched emitter-base contact underneath said emitter region;
an emitter metal onto said insulation layer and connected to all said trenched emitter-base contacts.

11. The semiconductor power device of claim 4, wherein said trench MOSFET monolithically integrated with said Schottky diode supported on a substrate heavily doped with a first conductivity type coated with drain metal on rear side, further comprising:
a plurality of trenched gates formed in an epitaxial layer lightly doped with a first conductivity type;
said trench MOSFET further comprising:
a plurality of body regions doped with a second conductivity type extending between every two adjacent of said trenched gates in said trench MOSFET portion;
a plurality of source regions heavily doped with said first conductivity type encompassed in said body regions;
a plurality of trenched source-body contacts penetrating through an insulation layer, said source regions and extending into said body regions in said trench MOSFET portion;
a body ohmic contact doped region heavily doped with said second conductivity type within said body region surrounding at least bottom of each said trenched source-body contact underneath said source region;
said Schottky diode further comprising:
a plurality of said trenched gates formed in said epitaxial layer lightly doped with said first conductivity type;
a plurality of trenched anode contacts penetrating through said insulation layer, and extending into said epitaxial layer between two adjacent said trenched gates in the Schottky diode portion;
a Schottky barrier height enhancement region lightly doped with said first conductivity type in contact with a silicide layer surrounding bottom and sidewall of each said trenched anode contact within said epitaxial layer.

12. The semiconductor power device of claim 5, wherein said trench MOSFET monolithically integrated with said soft recovery diode supported on a substrate heavily doped with a first conductivity type coated with drain metal on rear side, further comprising:
a plurality of trenched gates formed in an epitaxial layer lightly doped with a first conductivity type;
said trench MOSFET further comprising:
a plurality of body regions doped with a second conductivity type extending between every two adjacent of said trenched gates in the trench MOSFET portion;
a plurality of source regions heavily doped with said first conductivity type encompassed in said body regions;
a plurality of trenched source-body contacts penetrating through an insulation layer, said source regions and extending into said body regions in the trench MOSFET portion;
a body ohmic contact doped region heavily doped with said second conductivity type within said body region surrounding at least bottom of each said trenched source-body contact underneath said source region;
said soft recovery diode further comprising:
a plurality of trenched anode contacts penetrating through said insulation layer, and extending into said epitaxial layer between two adjacent said trenched gates in the soft recovery diode portion;
an anode doped region with said second conductivity type surrounding bottom and sidewall of each said trenched anode contact within said epitaxial layer in the soft recovery diode portion; and
said anode doped region having peak concentration less than 1E19 cm⁻³.

13. The semiconductor power device of claim 3, wherein said trench IGBT is a trench NPT IGBT monolithically integrated with said trench MOSFET and said fast switching diode which is a Schottky diode, and a termination region, further comprising:
a plurality of trenched gates formed in a FZ substrate lightly doped with a first conductivity type;
a heavily doped region with said first conductivity type disposed in bottom surface of said FZ substrate in said trench MOSFET portion as drain region, in said Schottky diode portion as cathode region and in said termination region;
said trench NPT IGBT further comprising:
a plurality of base regions doped with a second conductivity type extending between every two adjacent of said trenched gates in said trench NPT IGBT portion;
a plurality of emitter regions heavily doped with said first conductivity type encompassed in said base regions of said trench NPT IGBT;
a plurality of trenched emitter-base contacts penetrating through an insulation layer, said emitter regions and extending into said base regions in said trench NPT IGBT portion;
a base ohmic contact doped region heavily doped with said second conductivity type within said base region surrounding at least bottom of each said trenched emitter-base contact underneath said emitter region;
a collector region of said trench NPT IGBT heavily doped with said second conductivity type disposed in said bottom surface of said FZ substrate in said trench NPT IGBT portion;
said trench MOSFET further comprising:
a plurality of body regions doped with said second conductivity type extending between every two adjacent of said trenched gates in said trench MOSFET portion;
a plurality of source regions heavily doped with said first conductivity type encompassed in said body regions of said trench MOSFET;
a plurality of trenched source-body contacts penetrating through said insulation layer, said source regions and extending into said body regions in the trench MOSFET portion;
a body ohmic contact doped region heavily doped with said second conductivity type within said body region surrounding at least bottom of each said trenched source-body contact underneath said source region;
said Schottky diode further comprising:
a plurality of trenched anode contacts disposed between two adjacent said trenched gates penetrating through said insulation layer, and extending into said FZ substrate in said Schottky diode portion;
a Schottky barrier height enhancement region lightly doped with said first conductivity type surrounding bottom and sidewall of each said trenched anode contact within said FZ substrate in said Schottky diode portion; and
a front metal disposed onto said insulation layer connecting to said trenched emitter-base contacts, said trenched source-body contacts and said trenched anode contacts.

14. The semiconductor power device of claim 3, wherein said trench IGBT is a trench NPT IGBT monolithically integrated with said trench MOSFET and said fast switching diode which is a soft recovery diode, and a termination region, further comprising:
a plurality of trenched gates formed in a FZ substrate lightly doped with a first conductivity type;
a heavily doped region with said first conductivity type disposed in bottom surface of said FZ substrate in said trench MOSFET portion as drain region, in said soft recovery diode portion as anode region and in said termination region;
said trench NPT IGBT further comprising:
a plurality of base regions doped with a second conductivity type extending between every two adjacent of said trenched gates in said trench NPT IGBT portion;
a plurality of emitter regions heavily doped with said first conductivity type encompassed in said base regions of said trench NPT IGBT;
a plurality of trenched emitter-base contacts penetrating through an insulation layer, said emitter regions and extending into said base regions in said trench NPT IGBT portion;
a base ohmic contact doped region heavily doped with said second conductivity type within said base region surrounding at least bottom of each said trenched emitter-base contact underneath said emitter region;
a collector region of said trench NPT IGBT heavily doped with said second conductivity type disposed in said bottom surface of said FZ substrate in said trench NPT IGBT portion;
said trench MOSFET further comprising:
a plurality of body regions doped with said second conductivity type extending between every two adjacent of said trenched gates in said trench MOSFET portion;
a plurality of source regions heavily doped with said first conductivity type encompassed in said body regions of said trench MOSFET;
a plurality of trenched source-body contacts penetrating through said insulation layer, said source regions and extending into said body regions in said trench MOSFET portion;
a body ohmic contact doped region heavily doped with said second conductivity type within said body region surrounding at least bottom of each said trenched source-body contact underneath said source region;
said soft recovery diode further comprising:
a plurality of trenched anode contacts disposed between two adjacent said trenched gates penetrating through said insulation layer, and extending into said FZ substrate in said soft recovery diode portion;
an anode doped region of said soft recovery diode doped with said second conductivity type surrounding bottom and sidewall of each said trenched emitter-base contact within said FZ substrate in said soft recovery diode portion; and
a front metal disposed onto said insulation layer connecting to said trenched emitter-base contacts, said trenched source-body contacts and said trenched anode contacts.

15. The semiconductor power device of claim 8, wherein said ESD gate protection diode comprising an array of doped regions alternatively doped with said first and second conductivity type dopant with a first and last doped regions heavily doped with said first conductivity type dopant wherein said first doped region connected to an emitter metal of said trench IGBT and a source metal of said trench MOSFET, and said last doped region connected to a gate metal by trenched ESD contacts, and underneath each of said trenched ESD contacts, a trenched gate is formed as a buffer layer to avoid shortage of trenched ESD contacts in said ESD gate protection diode to base regions of said trench IGBT or body regions of said trench MOSFET.

16. The semiconductor power device of claim 4 further comprising a source metal deposited onto said insulation layer and connected to said source and body regions in said trench MOSFET and said Schottky barrier height enhancement region in said Schottky diode region through contact metal plugs filled in said trenched source-body contacts and said trenched anode contacts.

17. The semiconductor power device of claim 5 further comprising a source metal deposited onto said insulation layer and connected to said source and body regions in said trench MOSFET and said anode doped region in said soft recovery diode region through contact metal plugs filled in said trenched source-body contacts and said trenched anode contacts.
